(19) United States
(12) Patent Application Publication
(10) Pub. No.: US 2021/0134900 A1
(43) Pub. Date: May 6, 2021

(54) LIGHT EMITTING SUBSTRATE AND MANUFACTURING METHOD THEREOF, ELECTRONIC DEVICE

(71) Applicants: BEIJING BOE DISPLAY TECHNOLOGY CO., LTD., Beijing (CN); BOE TECHNOLOGY GROUP CO., LTD., Beijing (CN)

(72) Inventors: Mingxiao JIANG, Beijing (CN); Weifeng ZHOU, Beijing (CN); Ce NING, Beijing (CN)

(21) Appl. No.: 16/639,298

(22) PCT Filed: Mar. 29, 2019
(86) PCT No.: PCT/CN2019/080599

§ 371 Date: Feb. 14, 2020

(51) Int. Cl. H01L 27/32; H01L 51/56

(52) U.S. Cl. CPC H01L 27/3246; H01L 51/56

(57) ABSTRACT

A light emitting substrate and a manufacturing method thereof, and an electronic device are provided, the method includes: forming a pixel definition layer by a patterning process using a first mask, in which the pixel definition layer includes an opening and a partition portion defining the opening; forming a first electrode, in which the first electrode includes a first portion covering at least a part of the partition portion and includes a second portion in the opening; and forming an auxiliary electrode by a patterning process using the first mask, in which the auxiliary electrode is electrically connected with the first electrode, and the auxiliary electrode is on the partition portion.

### TECHNICAL FIELD

At least one embodiment of the present disclosure relates to a light emitting substrate and a manufacturing method thereof, and an electronic device.

### BACKGROUND

Light emitting substrate having Organic Light-Emitting Diode (OLED) has advantages of fast response, high brightness, bright color, light weight, low energy consumption and so on, and thus it has been widely used in display devices and light emitting devices. The light emitting substrate having the organic light-emitting diode usually includes a light emitting structure, and a cathode and an anode that are electrically connected to the light emitting structure. The cathode and the anode provide electrical signals to the light emitting structure to control light emitting conditions of the light emitting structure, so that electrical properties of the cathode and the anode affect light emitting quality of the light emitting structure.

### SUMMARY

At least one embodiment of the present disclosure provides a manufacturing method of a light emitting substrate, and the method comprises: forming a pixel definition layer by a patterning process using a first mask, in which the pixel definition layer includes an opening and a partition portion defining the opening; forming a first electrode, in which the first electrode comprises a first portion covering at least a part of the partition portion and comprises a second portion in the opening; and forming an auxiliary electrode by a patterning process using the first mask, in which the auxiliary electrode is electrically connected with the first electrode, and the auxiliary electrode is on the partition portion.

For example, in the manufacturing method of the light emitting substrate provided by at least one embodiment of the present disclosure, a surface, facing the first electrode, of the auxiliary electrode is in direct contact with a surface, facing the auxiliary electrode, of the first electrode.

For example, in the manufacturing method of the light emitting substrate provided by at least one embodiment of the present disclosure, the auxiliary electrode is formed after forming the first electrode, and the auxiliary electrode is on a side, away from the partition portion of the pixel definition layer, of the first electrode.

For example, in the manufacturing method of the light emitting substrate provided by at least one embodiment of the present disclosure, the forming the auxiliary electrode comprises: forming a sacrifice layer on a side, away from the pixel definition layer, of the first electrode by a patterning process using the first mask, in which the sacrifice layer exposes the first portion of the first electrode and covers the second portion of the first electrode; forming a conductive material layer, in which the conductive material layer includes a first portion and a second portion that are disconnected from each other; a first portion of the conductive material layer covers the first portion of the first electrode and is in direct contact with the first portion of the first electrode, a second portion of the conductive material layer is on a side, away from the second portion of the first electrode, of the sacrifice layer; and simultaneously removing the sacrifice layer and the second portion of the conductive material layer so that the first portion of the conductive material layer remains as the auxiliary electrode.

For example, in the manufacturing method of the light emitting substrate provided by at least one embodiment of the present disclosure, the sacrifice layer is a strippable layer, and the manufacturing method of the light emitting substrate further comprises: stripping the sacrifice layer to simultaneously remove the second portion of the conductive material layer which is on the sacrifice layer.

For example, in the manufacturing method of the light emitting substrate provided by at least one embodiment of the present disclosure, the forming the sacrifice layer comprises: forming a sacrifice material layer covering the first electrode; and performing a photolithography process on the sacrifice material layer by using the first mask to form the sacrifice layer, in which a material of the sacrifice layer comprises a first photoresist, the pixel definition layer is formed by a photolithographic process using a second photoresist and the first mask, and photosensitivity of the first photoresist is opposite to that of the second photoresist.

For example, in the manufacturing method of the light emitting substrate provided by at least one embodiment of the present disclosure, the forming the sacrifice layer comprises: forming a sacrifice material layer covering the first electrode, in which the sacrifice material layer is a strippable layer; forming a first photoresist layer on the sacrifice material layer; and performing a photolithography process on the sacrifice material layer by using the first mask and the first photoresist layer to form the sacrifice layer. A material of the first photoresist layer comprises a first photoresist, the pixel definition layer is formed by a photolithographic process using a second photoresist and the first mask, and photosensitivity of the first photoresist is opposite to that of the second photoresist.

For example, in the manufacturing method of the light emitting substrate provided by at least one embodiment of the present disclosure, the first photoresist is negative photoresist and the second photoresist is positive photoresist; or, the first photoresist is positive photoresist and the second photoresist is negative photoresist.

For example, in the manufacturing method of the light emitting substrate provided by at least one embodiment of the present disclosure, the auxiliary electrode is formed before forming the first electrode, the auxiliary electrode is on a side, close to the partition portion of the pixel definition layer, of the first electrode.

For example, in the manufacturing method of the light emitting substrate provided by at least one embodiment of the present disclosure, the forming the sacrifice layer comprises: forming a conductive material layer covering the pixel definition layer; and performing a photolithography process on the conductive material layer using the first mask and a first photoresist to form the auxiliary electrode; and the pixel definition layer is formed by a photolithography process using the first mask and a second photoresist, and photosensitivity of the first photoresist is same as that of the second photoresist.

For example, in the manufacturing method of the light emitting substrate provided by at least one embodiment of the present disclosure, the conductive material layer is formed by an evaporation method.

For example, in the manufacturing method of the light emitting substrate provided by at least one embodiment of the present disclosure, a material of the first electrode is a metal material; a thickness of the first electrode is not more than 20 nm in a direction from a surface, away from the pixel definition layer, of the first electrode to a surface, close to the pixel definition layer, of the first electrode.

For example, the manufacturing method of the light emitting substrate provided by at least one embodiment of the present disclosure further comprises: forming a second electrode and a light emitting layer in the opening of the pixel definition layer, in which the second electrode is opposite to the first electrode, and the light emitting layer is between the first electrode and the second electrode, and light emitted by the light emitting layer exits through the first electrode.

At least one embodiment of the present disclosure further provides a light emitting substrate comprising: a pixel definition layer, a first electrode and an auxiliary electrode. The pixel definition layer comprises an opening and a partition portion; the first electrode comprises a first portion and a second portion; the first portion is on the partition portion and covers at least a part of the partition portion, and the second portion is in the opening; the auxiliary electrode is in contact with the first electrode in a surface-to-surface manner to be electrically connected with the first electrode, and is on the partition portion; the auxiliary electrode and the pixel definition layer have a substantially same pattern.

For example, in the light emitting substrate provided by at least one embodiment of the present disclosure, the auxiliary electrode is on a side, away from the partition portion of the pixel definition layer, of the first electrode.

For example, in the light emitting substrate provided by at least one embodiment of the present disclosure, the auxiliary electrode is on a side, close to the partition portion of the pixel definition layer, of the first electrode.

For example, in the light emitting substrate provided by at least one embodiment of the present disclosure, a material of the first electrode is a metal material; and a thickness of the first electrode is not more than 20 nm in a direction from a surface, away from the pixel definition layer, of the first electrode to a surface, close to the pixel definition layer, of the first electrode.

For example, the light emitting substrate provided by at least one embodiment of the present disclosure further comprises: a second electrode and a light emitting layer which are in the opening of the pixel definition layer; the second electrode is opposite to the first electrode, and the light emitting layer is between the first electrode and the second electrode; and light emitted by the light emitting layer exits through the first electrode.

At least one embodiment of the present disclosure further provides an electronic device comprising any one of the light emitting substrates provided by the embodiments of the present disclosure.

### BRIEF DESCRIPTION OF THE DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative of the disclosure.

FIG. 1A-FIG. 1G are schematic diagrams of a manufacturing method of a light emitting substrate provided by some embodiments of the present disclosure;

FIG. 2A-FIG. 2D are another schematic diagrams of the manufacturing method of the light emitting substrate provided by some embodiments of the present disclosure;

FIG. 3A-FIG. 3D are further another schematic diagrams of the manufacturing method of the light emitting substrate provided by some embodiments of the present disclosure;

FIG. 4A is a schematic planar view of the light emitting substrate provided by some embodiments of the present disclosure;

FIG. 4B is a schematic cross-sectional view taken along a line I-I′ in FIG. 4A;

FIG. 4C is another schematic cross-sectional view taken along the line I-I′ in FIG. 4A;

FIG. 5 is a schematic diagram of an electronic device provided by some embodiments of the disclosure.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment (s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present application for disclosure, are not intended to indicate any sequence, amount or importance, but distinguish various components. Also, the terms “comprise,” “comprising,” “include,” “including,” etc., are intended to specify that the elements or the objects stated before these terms encompass the elements or the objects and equivalents thereof listed after these terms, but do not preclude the other elements or objects. “In,” “out,” “on,” “under” and the like are only used to indicate relative position relationship, and when the position of the object which is described is changed, the relative position relationship may be changed accordingly.

The figures in embodiments of the present disclosure are not drawn according to actual proportions or scales. An amount and specific size of each structure may be determined according to actual acquirements. The figures of the embodiments of the present disclosure are only schematic views.

It should be noted that the feature “strippable layer” refers to a structural layer that can be removed by a stripping process or lift-off process in the present disclosure.

It should be noted that, in the present disclosure, the feature “a surface, facing the first electrode, of the auxiliary electrode is in direct contact with a surface, facing the auxiliary electrode, of the first electrode” refers to that the entire surface, facing the first electrode, of the auxiliary electrode is in contact with the surface of the first electrode, that is, in the direction perpendicular to the substrate, no other intermediate layer or intermediate structure exists between any position of the entire surface, facing the first electrode, of the auxiliary electrode and the surface, facing the auxiliary electrode, of the first electrode.

In a manufacturing method of an organic light-emitting diode (OLED) substrate, the auxiliary cathode is usually be directly deposited by using a vapor deposition mask. However, on one hand, this solution needs to add the vapor deposition mask (e.g., fine metal mask (FMM)), and a metal material that to be deposited may adhere to the vapor deposition mask and thus the vapor deposition mask is difficult to be cleaned, resulting in a limited lifetime of the vapor deposition mask, thus increasing a cost of mask; on the other hand, this solution is suitable for manufacturing specific small-sized or medium-sized substrates, and is not easy to realize or has a high cost for large-sized substrates. Alternatively, in some manufacturing methods of the organic light-emitting diode substrate, the auxiliary cathode is fabricated on an encapsulation plate, and then the auxiliary cathode is electrically connected with the cathode when the encapsulation plate is bonded with the organic light-emitting diode substrate; this method requires a separate mask for forming the auxiliary cathode and is not suitable for thin film encapsulation. Or, in some manufacturing methods of the organic light-emitting diode substrate, an insulation layer is firstly manufactured on the transparent cathode and a via hole passing through the insulation layer is manufactured, the auxiliary cathode is manufactured on the insulating layer, and the auxiliary cathode is connected with the transparent cathode through the via hole; this solution requires additional steps for manufacturing the insulation layer and the via hole, and the mask for forming the via hole and the mask for manufacturing the auxiliary cathode are separately manufactured, thus greatly increasing a manufacturing cost.

At least one embodiment of the present disclosure provides a manufacturing method of a light emitting substrate, and the method comprises: forming a pixel definition layer by a patterning process using a first mask, in which the pixel definition layer includes an opening and a partition portion defining the opening; forming a first electrode, in which the first electrode comprises a first portion covering at least a part of the partition portion and comprises a second portion in the opening; and forming an auxiliary electrode by a patterning process using the first mask, in which the auxiliary electrode is electrically connected with the first electrode, and the auxiliary electrode is on the partition portion.

In the manufacturing method of the light emitting substrate provided by the embodiments of the present disclosure, the pixel definition layer and the auxiliary electrode are formed by using a same mask (i.e. the first mask), so that the mask for forming the auxiliary electrode does not need to be separately prepared, a process of forming the auxiliary electrode is simplified, and a cost for manufacturing the mask is saved. Providing the auxiliary electrode is equivalent to adding a circuit connected in parallel with the first electrode, so that an overall resistance of the first electrode structure (referring to an overall resistance of the electrode structure constituted by the first electrode and the auxiliary electrode) is reduced, a signal transmission speed is improved, and Joule heat is reduced, thereby being beneficial to prolonging a service life of the light emitting substrate and reducing energy consumption. For example, especially in a case where a thickness of the first electrode is small (for example, in a case where the first electrode is made of a metal material and is transparent to light, or in a case where the thickness of the first electrode is reduced in order to obtain an ultra-thin light emitting substrate, etc.), resulting in that a resistance of the first electrode is large and a phenomenon of excessive large resistance at some positions because of uneven thickness of the first electrode is easy to exist, this auxiliary cathode avoids or reduces this phenomenon. In addition, forming the auxiliary cathode on the partition portion (non-opening region) of the pixel definition layer improves performances of the first electrode without affecting the light transmittance ratio. The manufacturing method of the light emitting substrate provided by at least one embodiment of the disclosure is suitable for manufacturing light emitting substrates of various sizes, and a size range of the substrate to which the manufacturing method can be applicable is wide.

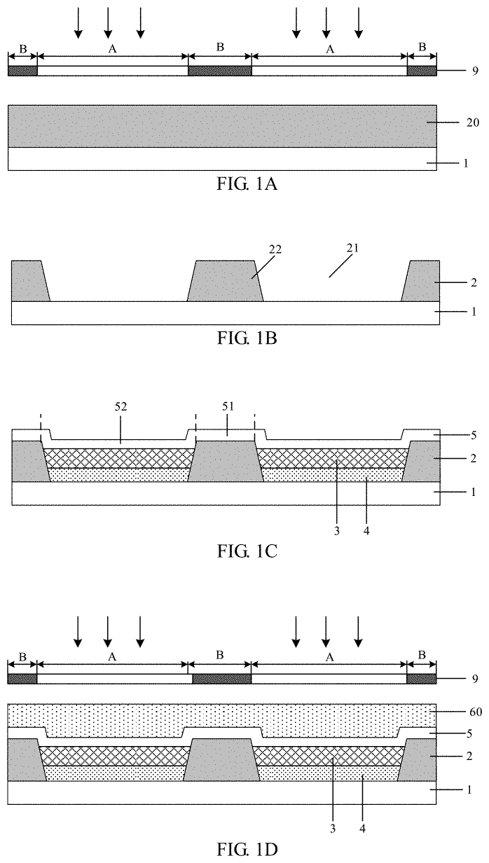

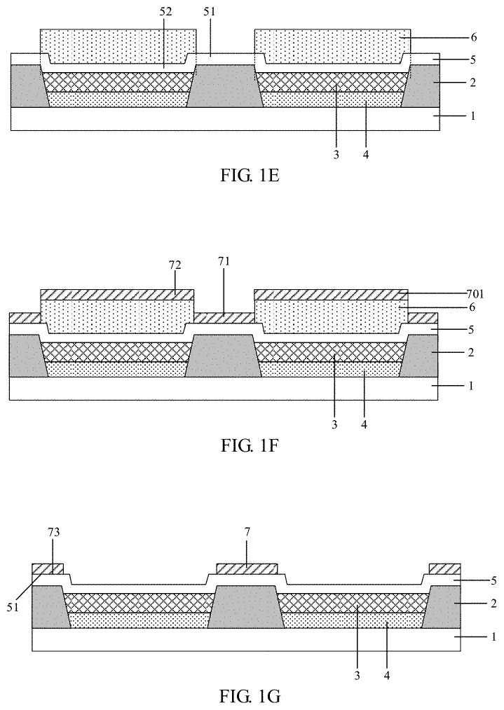

Illustratively, FIG. 1A-FIG. 1G are schematic diagrams of the manufacturing method of the light emitting substrate provided by some embodiments of the disclosure.

For example, the manufacturing method of the light emitting substrate includes forming the auxiliary electrode using a first photoresist and the first mask. Before forming the auxiliary electrode, the manufacturing method of the light emitting substrate further includes forming the pixel definition layer by a patterning process using the first mask, for example, forming the pixel definition layer by the photolithography process using a second photoresist and the first mask. As illustrated in FIG. 1A, a base substrate 1 is provided, and a pixel definition material layer 20 is formed on the base substrate 1. For example, the base substrate 1 includes a driving circuit for driving a light emitting diode element formed subsequently. For example, in a case where the light emitting substrate is a display substrate, the display substrate includes a plurality of pixel units arranged in an array, and the driving circuit is a pixel circuit of each pixel unit. The pixel circuit includes a plurality of transistors, capacitors, etc., and for example, the pixel circuit is 2T1C (i.e., two transistors with one capacitor) type, 4T2C type, and the like. No limitation is imposed to the driving circuit in the embodiments of the present disclosure. For example, a material of the pixel definition material layer 20 includes the second photoresist, and for example, the pixel definition material layer 20 is formed by a coating method. In the embodiments, the manufacturing method of the light emitting substrate is described taking a case that the second photoresist is positive photoresist as an example. The pixel definition material layer 20 is exposed using the first mask 9. The first mask 9 includes a transparent region A and a non-transparent region B. Then, a developing process is performed to form the pixel definition layer 2 as illustrated in FIG. 1B. The pixel definition layer 2 includes the opening 21 and the partition portion 22 defining the opening 21. For example, in other embodiments, the material of the pixel definition material layer 20 does not include the photoresist, for example, the material of the pixel definition material layer 20 is an inorganic material including at least one selected from a group consisting of silicon nitride, silicon oxide and silicon oxynitride. In this case, the pixel definition material layer 20 is formed by, for example, a deposition method or the like, and the manufacturing method of the light emitting substrate further includes forming a second photoresist layer (not illustrated) including the second photoresist on the pixel definition material layer 20, and then performing an exposure process, a development process, and an etching process on the pixel definition material layer 20 using the first mask 9 and the second photoresist layer, to form the pixel definition layer 2 as illustrated in FIG. 1B. No limitation is imposed to the material and the specific manufacturing method of the pixel definition layer 2 in the embodiments of the present disclosure.

As illustrated in FIG. 1C, the manufacturing method of the light emitting substrate further includes: forming a second electrode 4, a light emitting layer 3 and the first electrode 5 in the opening 21 of the pixel definition layer 2. For example, the first electrode 5, the light emitting layer 3, and the second electrode 4 constitute the light emitting diode. For example, the light emitting layer 3 is an organic light emitting layer or an inorganic light emitting layer, and correspondingly, the light emitting diode is an organic light emitting diode (OLED) or an inorganic light emitting diode. The organic light emitting layer may be a composite structure layer, including, for example, an electron injection layer, an electron transport layer, a light emitting function layer, a hole transport layer, and a hole injection layer that are stacked. Electrons reach the light emitting function layer through the electron injection layer and the electron transport layer, holes reach the light emitting function layer through the hole injection layer and the hole transport layer, and the electrons and the holes meet each other to form excitons in the light emitting function layer, and then light is emitted because of excitation of the excitons. The light emitting function layer may include various suitable types of materials, such as fluorescent light emitting materials or phosphorescent light emitting materials, such as red light emitting materials, green light emitting materials, blue light emitting materials or white light emitting materials, etc. No limitation is imposed to the material of the light emitting layer in the embodiments of the present disclosure.

For example, in a case illustrated in FIG. 1C, the second electrode 4, the light emitting layer 3 and the first electrode 5 are sequentially formed. For example, a material of the second electrode 4 is a metal material, and the second electrode 4 is formed by a sputtering method or an evaporation method, and then the light emitting layer 3 of the light emitting diode is formed on the second electrode 4, and the second electrode 4 is electrically connected with the driving circuit for the light emitting diode element. The second electrode 4 is opposite to the first electrode 5, and the light emitting layer 3 is between the first electrode 5 and the second electrode 4. The first electrode 5 includes the first portion 51 covering at least a part of the partition portion 22 and includes the second portion 52 located in the opening 21. For example, a material of the first electrode 5 is a metal material; the metal material is, for example, a metal with a small work function, such as magnesium or silver, so as to reduce damage to the light emitting layer 3 in the process of forming the first electrode 5 by the evaporation method. For example, a thickness of the first electrode 5 in a direction perpendicular to the base substrate 1 is not more than 20 nm, so that the first electrode 5 is transparent to light, light emitted by the light emitting layer 3 exits through the first electrode 5, and the first electrode 4 is opaque; that is, the light emitting substrate is of a top emission type. Of course, in some other embodiments, the light emitting substrate may be of a bottom emission type, that is, the light emitted by the light emitting layer 3 exits through the second electrode 4. At least one embodiment of the present disclosure takes the top emission type as an example. Of course, the embodiments of the present disclosure does not limit the order of the steps of forming the pixel definition layer 2 and the steps of forming the first electrode 4 and the light emitting layer 3.

The manufacturing method of the light emitting substrate further comprises: forming the auxiliary electrode by a patterning process using the first mask, in which the auxiliary electrode is electrically connected with the first electrode, and the auxiliary electrode is on the partition portion.

For example, in one embodiment, the auxiliary electrode is formed after forming the first electrode, and the auxiliary electrode is on a side, away from the partition portion of the pixel definition layer, of the first electrode.

Illustratively, as illustrated in FIG. 1D, a sacrifice material layer 60 covering the first electrode 5 is formed on the side, away from the pixel definition layer 2, of the first electrode 5. For example, a material of the sacrifice material layer 60 includes a first photoresist, photosensitivity of the first photoresist is opposite to that of the second photoresist mentioned above. In this embodiment, the first photoresist is negative photoresist, and correspondingly, the second photoresist is positive photoresist. Or, in other embodiments, the first photolithography is positive photoresist, and correspondingly, the second photoresist is negative photoresist. For example, the sacrifice material layer 60 is formed by a coating method.

Then, a photolithography process is performed on the sacrifice material layer 60 using the first mask 9 to form a sacrifice layer. For example, the sacrifice material layer 60 is exposed and developed using the first mask 9 to form the sacrifice layer 6 as illustrated in FIG. 1E. That is, the sacrifice layer 6 is formed on the side, away from the pixel definition layer 2, of the first electrode 5 by a patterning process using the first mask 9. The first mask 9 is the same mask as the first mask 9 applied in the photolithography process for forming the pixel definition layer 2. Because the photosensitivity of the first photoresist is opposite to the photosensitivity of the second photoresist, a pattern of the sacrifice layer 6 is complementary to a pattern of the pixel definition layer 2. The sacrifice layer 6 exposes the first portion 51 of the first electrode and covers the second portion 52 of the first electrode.

The photoresist layer is capable of being stripped, a material of the sacrifice material layer 60 for example is the first photoresist, and thus the sacrifice material layer 60 is a strippable layer, i.e., the sacrifice layer is a strippable layer. The strippable layer can be removed by a stripping process.

As illustrated in FIG. 1F, a conductive material layer 701 is formed. For example, the conductive material layer 701 is formed by an evaporation method. Compared with a sputtering process, the evaporation method reduces damage to the light emitting layer 3 and is beneficial to protecting the light emitting layer 3. Because of the step formed by the sacrifice layer 6, the conductive material layer 701 includes a first portion 71 and a second portion 72 that are disconnected from each other at an edge of the sacrifice layer 6. The first portion 71 of the conductive material layer 701 covers the first portion 51 of the first electrode 5 and is in direct contact with the first portion 51 of the first electrode, and the second portion 72 of the conductive material layer 701 is on a side, away from the second portion 52 of the first electrode, of the sacrifice layer 6. It should be noted that “disconnected from each other” in the embodiments of the present disclosure refers to that the first portion 71 of the conductive material layer and the second portion 72 of the conductive material layer are not in contact with each other and thus are not connected with each other.

As illustrated in FIG. 1G, the manufacturing method of the light emitting substrate further includes stripping off the sacrifice layer 6 to simultaneously remove the second portion 72 of the conductive material layer which is on the sacrifice layer 6, so as to retain the first portion 71 of the conductive material layer as the auxiliary electrode 7, that is, simultaneously removing the sacrifice layer and the second portion of the conductive material layer so that the first portion of the conductive material layer serves as the auxiliary electrode. Because the operation of the stripping process is simple, the step of simultaneously removing the second portion 72 of the conductive material layer which is on the sacrifice layer 6 by stripping the sacrifice layer 6 is beneficial to simplifying the process and improving a production efficiency.

As illustrated in FIG. 1G, a surface 73, facing the first electrode 5, of the auxiliary electrode 7 is in direct contact with a surface 51, facing the auxiliary electrode 7, of the first electrode 5, that is, the entire surface 73 is in direct contact with the surface 51, so as to reduce a contact resistance between the first electrode 5 and the auxiliary electrode 7, and an overall resistance of the conductive structure constituted by the first electrode 5 and the auxiliary electrode 7 is reduced, thereby reducing a voltage drop caused by the overall resistance and reducing resistance heating during operation.

It should be noted that, in the embodiments of the present disclosure, the term “the entire surface 73 is in direct contact with the surface 51” refers to that no other layer or structure exists between any position of an entirety of the surface 73 and the surface 51.

It should be noted that the auxiliary electrode 7 and the pixel definition layer 2 have a substantially same pattern. For example, in the process of exposing the pixel definition material layer 20 and the process of exposing the sacrifice material layer 60, by using a sufficiently strong illumination intensity, both a cross-sectional shape of the partition portion 22 of the formed pixel definition layer in the direction perpendicular to the base substrate 1 and a cross-sectional shape of the sacrifice layer 6 in the direction perpendicular to the base substrate 1 are rectangular or approximately rectangular (as illustrated in FIG. 1E), so that the auxiliary electrode 7 and the pixel definition layer 2 have the same pattern. Of course, there may be errors in the manufacturing process so that a width of the pattern of the auxiliary electrode 7 is not completely same as a width of the pattern of the pixel definition layer 2.

For example, in the case where the first photoresist is negative photoresist and the second photoresist is positive photoresist, the cross-sectional shape of the formed sacrifice layer 6 in the direction perpendicular to the base substrate 1 is trapezoidal, and a length of an upper bottom, away from the base substrate 1, of the trapezoidal pattern is larger than a length of a lower bottom, close to the base substrate 1, of the trapezoidal pattern (not illustrated in the figure), thus a width, in a certain direction in a plane where the auxiliary electrode is located, of the auxiliary electrode formed subsequently is less than a width in the certain direction of the pixel definition layer 2. For another example, in the case where the first photoresist is positive photoresist and the second photoresist is negative photoresist, the cross-sectional shape of the formed sacrifice layer 6 in the direction perpendicular to the base substrate 1 is trapezoidal, and the length of the upper bottom, away from the base substrate 1, of the trapezoidal pattern is smaller than the length of the lower bottom, close to the base substrate 1, of the trapezoidal pattern (not illustrated in the figure), thus the width, in a certain direction in the plane where the auxiliary electrode is located, of the auxiliary electrode formed subsequently is larger than the width in the certain direction of the pixel definition layer 2. It is within the scope protected by this disclosure that the auxiliary electrode 7 and the pixel definition layer 2 have the substantially same pattern in consideration of dimensional errors in the process.

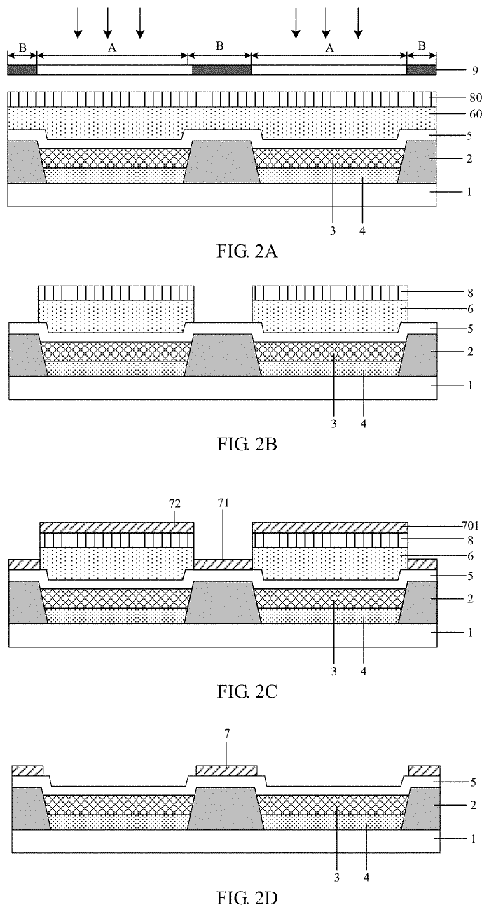

FIG. 2A-FIG. 2D are another schematic diagrams of the manufacturing method of the light emitting substrate provided by the embodiments of the present disclosure. This embodiment of FIG. 2A-FIG. 2D has the following differences from the embodiment illustrated in FIG. 1A-FIG. 1G After forming the structure illustrated in FIG. 1C, as illustrated in FIG. 2A, the sacrifice material layer 60 covering the first electrode 5 is formed. The sacrifice material layer 60 is a strippable layer. For example, a material of the sacrifice material layer 60 does not include photoresist material. In this case, for example, the sacrifice material layer 60 is a strippable layer other than the photoresist layer, such as a strippable organic coating layer, which may be selected by those skilled in the art. After the sacrifice material layer 60 is formed, a first photoresist material layer 80 is formed on the sacrifice material layer 60. A material of the first photoresist layer 80 includes the first photoresist. The photosensitivity of the first photoresist is opposite to that of the second photoresist. A photolithography process is performed on the sacrifice material layer 60 by using the first mask 9 and the first photoresist material layer 80 to form the sacrifice layer. For example, an exposure process, a development process and an etching process are performed on the sacrifice material layer 60 to form the first photoresist layer 8 and the sacrifice layer 6 as illustrated in FIG. 2B. For example, the sacrifice material layer 60 is etched by a dry etching method to prevent an etchant in a wet etching method from damaging the light emitting diode.

As illustrated in FIG. 2C, then the conductive material layer 701 is formed. Because of the step formed by the sacrifice layer 6, the conductive material layer 701 includes the first portion 71 and the second portion 72 that are disconnected from each other at the edge of the sacrifice layer 6. The first portion 71 of the conductive material layer covers and is in direct contact with the first portion 51 of the first electrode; the second portion 72 of the conductive material layer is on the side, away from the second portion 52 of the first electrode, of the sacrifice layer 6 and is on the side, away from the sacrifice layer 6, of the first photoresist layer 8.

As illustrated in FIG. 2D, the manufacturing method of the light emitting substrate further includes stripping off the sacrifice layer 6 to simultaneously remove the first photoresist layer 8 and the second portion 72 of the conductive material layer which are on the sacrifice layer 6, so as to retain the first portion 71 of the conductive material layer as the auxiliary electrode 7.

For the embodiment illustrated in FIG. 2A-FIG. 2D, technical features such as processes and steps not mentioned are the same as those described in the embodiment illustrated in FIG. 1A-FIG. 1G, please refer to the previous description.

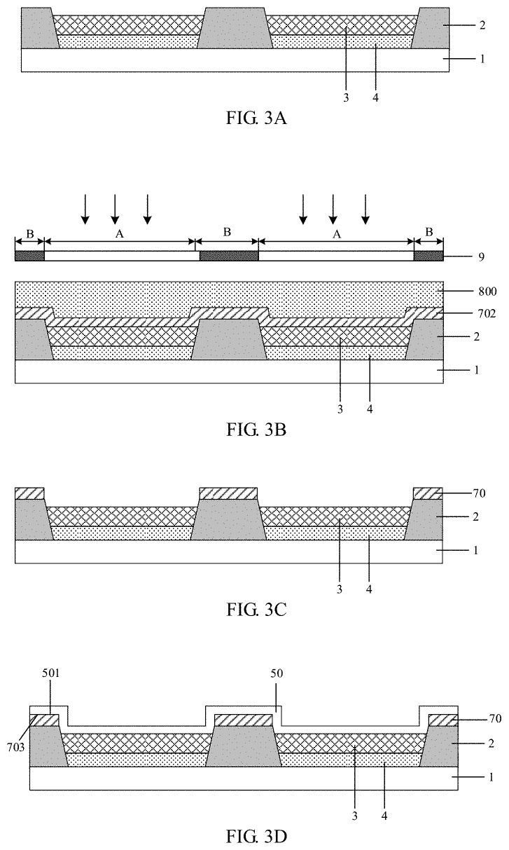

FIG. 3A-FIG. 3D are further another schematic diagrams of the manufacturing method of the light emitting substrate provided by some embodiments of the present disclosure. This embodiment has the following differences from the embodiment illustrated in FIG. 1A-FIG. 1G In the embodiment illustrated in FIG. 3A-FIG. 3D, the auxiliary electrode is formed before forming the first electrode, and the auxiliary electrode is on a side, close to the partition portion of the pixel definition layer, of the first electrode.

Illustratively, as illustrated in FIG. 3A, the pixel definition layer 2, the first electrode 4, and the light emitting layer 3 are formed by the previously described method.

Then, as illustrated in FIG. 3B, a conductive material layer 702 covering the pixel definition layer 2 is formed. For example, the conductive material layer 702 is formed by the evaporation method. Compared with the sputtering method, the evaporation method reduces damage to the light emitting layer 3 and is beneficial to protecting the light emitting layer 3. A first photoresist layer 800 covering the conductive material layer 702 is formed, and the first photoresist layer 800 includes the first photoresist. The photosensitivity of the first photoresist is the same as the photosensitivity of the second photoresist, so that the auxiliary electrode 70 and the pixel definition layer 2 have the substantially same pattern. For example, in this embodiment, the first photoresist and the second photoresist are both positive photoresist. For example, in other embodiments of the present disclosure, both the first photoresist and the second photoresist are negative photoresist. Then, a photolithography process is performed on the conductive material layer 702 by using the first mask 9 and the first photoresist layer 800 to form the auxiliary electrode 70 as illustrated in FIG. 3C. The auxiliary electrode 70 is on the side, close to the partition portion 22 of the pixel definition layer, of the first electrode 5.

As illustrated in FIG. 3D, the manufacturing method of the light emitting substrate further includes: forming the first electrode 50 after forming the auxiliary electrode 70. The first electrode 50 covers the auxiliary electrode 70 and the light emitting layer 3, and a surface 703, facing the first electrode 5, of the auxiliary electrode 70 is in direct contact with a surface 501, facing the auxiliary electrode 7, of the first electrode 5, that is, the entire surface 703 is in direct contact with the surface 501, so as to reduce a contact resistance of the first electrode 50 and the auxiliary electrode 70. It should be noted that, in the embodiments of the present disclosure, the term “the entire surface 703 is in direct contact with the surface 501” refers to that there are no other layers or structures between any position of an entirety of the surface 703 and the surface 501.

For the embodiment illustrated in FIG. 3A-FIG. 3D, the processes, steps and other technical features not mentioned (e.g., a material of the first electrode, a material of the auxiliary electrode, etc.) are the same as those described in the embodiment illustrated in FIG. 1A-FIG. 1G, please refer to the previous descriptions.

At least one embodiment of the disclosure further provides a light emitting substrate, and the light emitting substrate comprising: a pixel definition layer, a first electrode and an auxiliary electrode; the pixel definition layer comprises an opening and a partition portion; the first electrode comprises a first portion and a second portion, the first portion is on the partition portion and covers at least a part of the partition portion, and the second portion is in the opening; the auxiliary electrode is in contact with the first electrode in a surface-to-surface manner to be electrically connected with the first electrode and is on the partition portion; the auxiliary electrode and the pixel definition layer have a substantially same pattern.

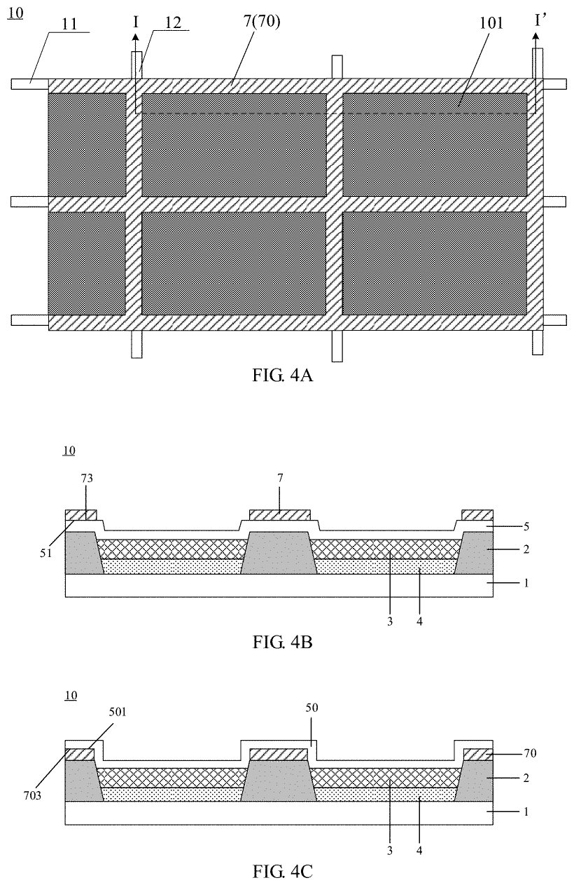

FIG. 4A is a schematic planar view of the light emitting substrate provided by the embodiments of the present disclosure, and FIG. 4B is a schematic cross-sectional view taken along a line I-I′ in FIG. 4A. The light emitting substrate provided by the embodiments of the disclosure is obtained by the manufacturing method of the light emitting substrate provided by at least one embodiment of the present disclosure.

As illustrated in FIG. 4A and FIG. 4B, for example, the light emitting substrate 10 includes gate lines 11 and data lines 12 that intersect with each other to define a plurality of light emitting units 101 arranged in an array, the light emitting units 101 for example are pixel units, each light emitting unit include at least one light emitting diode, and one of the gate lines 11 and one of the data lines 12 are respectively electrically connected with the driving circuit in each light emitting unit, so as to provide scanning signals and data signals to control whether the light emitting diode in the light emitting unit to emit light or not and control the light emitting intensity. For example, the auxiliary electrode 7(70) is disposed to surround each light emitting unit of the plurality of light emitting units 101. For example, the light emitting substrate 10 includes: a base substrate 1, the pixel definition layer 2, the first electrode 5 and the auxiliary electrode 7 that are disposed on the base substrate 1. The pixel definition layer 2 includes the opening 21 and the partition portion 22. The first electrode 5 includes the first portion 51 and the second portion 52, the first portion 51 is on the partition 22 and covers at least a part of the partition portion 22, and the second portion 52 is in the opening 21. The auxiliary electrode 7 is in contact with the first electrode 5 in the surface-to-surface manner to be electrically connected with the first electrode 5 and is on the partition portion 22. Providing the auxiliary electrode is equivalent to adding a circuit connected in parallel with the first electrode, so that an overall resistance of the cathode structure constituted by the auxiliary electrode 7 and the first electrode 5 is reduced, a signal transmission speed is improved, and Joule heat is reduced, thereby being beneficial to prolonging a service life of the light emitting substrate and reducing energy consumption. Especially in a case where a thickness of the first electrode is small (for example, in a case where the first electrode is made of a metal material and is transparent to light, or in a case where the thickness of the first electrode is reduced in order to obtain an ultra-thin light emitting substrate, etc.), resulting in that a resistance of the first electrode is large and a phenomenon of excessive large resistance at some positions because of uneven thickness of the first electrode is easy to exist, the auxiliary cathode avoids or reduces this phenomenon.

It should be noted that the term “the auxiliary electrode 7 is in contact with the first electrode 5 in the surface-to-surface manner” refers to that a surface 73, facing the first electrode 5, of the auxiliary electrode 7 is in contact with a surface 51, facing the auxiliary electrode 7, of the first electrode 5, that is, there is no other layer or structure between any position of the entire surface 73 and the surface 51, so as to reduce the contact resistance between the auxiliary electrode 7 and the first electrode 5, and simplify the manufacturing process, such as omitting a process of manufacturing a via hole connecting the auxiliary electrode 7 and the first electrode 5. The auxiliary electrode 7 and the pixel definition layer 2 have a substantially same pattern, i.e., the auxiliary cathode 7 is located in a non-opening region of the pixel definition layer, which improves performances of the first electrode without affecting a light transmittance ratio, and enables the pixel definition layer and the auxiliary cathode to be formed using the same mask in the process of manufacturing the light emitting substrate 10, thereby saving cost, simplifying the process, and widening a size range of the substrate to which the manufacturing method can be applicable.

For example, the auxiliary electrode 7 is on a side, away from the partition portion 22 of the pixel definition layer, of the first electrode 5.

For example, the light emitting substrate 10 further includes a second electrode 4 and a light emitting layer 3 that are in the opening 21 of the pixel definition layer 2. The light emitting layer 3 is between the first electrode 5 and the second electrode 4, and the second electrode 4 is opposite to the first electrode 5. For example, a material of the first electrode 5 is a metal material. The metal material is, for example, a metal with a small work function, such as magnesium or silver, to reduce damage to the light emitting layer 3 in the process of forming the first electrode 5 by an evaporation method. For example, a thickness of the first electrode 5 in a direction perpendicular to the base substrate 1 is not more than 20 nm, so that the first electrode 5 is transparent to light, light emitted by the light emitting layer 3 exits through the first electrode 5, and the first electrode 4 is opaque. That is, the light emitting substrate is of a top emission type. For example, the light emitting layer 3 includes a light emitting function layer, and the first electrode 5 and the second electrode 4 are respectively electrically connected with the light emitting function layer to control operation states of the light emitting function layer.

FIG. 4C is another schematic cross-sectional view taken along the line I-I′ in FIG. 4A. The light emitting substrate illustrated in FIG. 4C differs from the light emitting substrate illustrated in FIG. 4B in that the auxiliary electrode 70 is on a side, close to the partition 22 of the pixel definition layer, of the first electrode 50.

In this embodiment, features of the light emitting substrate that are not mentioned, such as a material of the auxiliary cathode 7, a material and a thickness of the first electrode 5, and the corresponding technical effects are the same as those in the above embodiment of the manufacturing method of the light emitting substrate, please refer to the previous descriptions and are not repeated here.

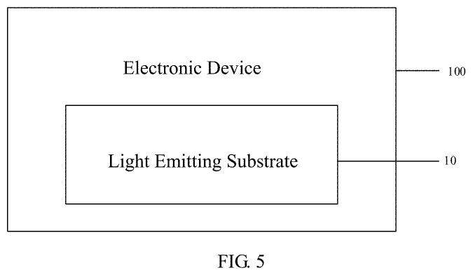

At least one embodiment of the present disclosure further provides an electronic device including any one of the light emitting substrates provided by the embodiments of the present disclosure. Illustratively, FIG. 5 is a schematic diagram of the electronic device provided by the embodiments of the present disclosure. As illustrated in FIG. 5, the electronic device 100 provided by the embodiments of the present disclosure includes any one of the light emitting substrates 10 provided by the embodiments of the present disclosure. For example, the electronic device 100 may be a display device, such as an organic light emitting diode (OLED) display device. The display device may be implemented as any product or component having a display function, such as a mobile phone, a tablet computer, a television, a display, a notebook computer, a digital photo frame, a navigator, etc. The electronic device 100 may also be a lighting device, a decorative lamp, or the like. Regarding other structures of the display device, those skilled in the art may refer to common techniques.

What have been described above are only specific implementations of the present disclosure, the protection scope of the present disclosure is not limited thereto. The protection scope of the present disclosure should be defined by the claims.

In the claims:

1. A manufacturing method of a light emitting substrate, comprising:
forming a pixel definition layer by a patterning process using a first mask, wherein the pixel definition layer includes an opening and a partition portion defining the opening;
forming a first electrode, wherein the first electrode comprises a first portion covering at least a part of the partition portion and comprises a second portion in the opening; and
forming an auxiliary electrode by a patterning process using the first mask, wherein the auxiliary electrode is electrically connected with the first electrode, and the auxiliary electrode is on the partition portion.

2. The manufacturing method of the light emitting substrate according to claim 1, wherein
a surface, facing the first electrode, of the auxiliary electrode is in direct contact with a surface, facing the auxiliary electrode, of the first electrode.

3. The manufacturing method of the light emitting substrate according to claim 1, wherein
the auxiliary electrode is formed after forming the first electrode, and the auxiliary electrode is on a side, away from the partition portion of the pixel definition layer, of the first electrode.

4. The manufacturing method of the light emitting substrate according to claim 3, wherein the forming the auxiliary electrode comprises:
forming a sacrifice layer on a side, away from the pixel definition layer, of the first electrode by a patterning process using the first mask, wherein the sacrifice layer exposes the first portion of the first electrode and covers the second portion of the first electrode;
forming a conductive material layer, wherein the conductive material layer includes a first portion and a second portion that are disconnected from each other; a first portion of the conductive material layer covers the first portion of the first electrode and is in direct contact with the first portion of the first electrode, a second portion of the conductive material layer is on a side, away from the second portion of the first electrode, of the sacrifice layer; and
simultaneously removing the sacrifice layer and the second portion of the conductive material layer so that the first portion of the conductive material layer remains as the auxiliary electrode.

5. The manufacturing method of the light emitting substrate according to claim 4, wherein
the sacrifice layer is a strippable layer; and
the manufacturing method of the light emitting substrate further comprises: stripping the sacrifice layer to simultaneously remove the second portion of the conductive material layer which is on the sacrifice layer.

6. The manufacturing method of the light emitting substrate according to claim 4, wherein
the forming the sacrifice layer comprises: forming a sacrifice material layer covering the first electrode, and performing a photolithography process on the sacrifice material layer by using the first mask to form the sacrifice layer; and
a material of the sacrifice layer comprises a first photoresist, the pixel definition layer is formed by a photolithographic process using a second photoresist and the first mask, and photosensitivity of the first photoresist is opposite to that of the second photoresist.

7. The manufacturing method of the light emitting substrate according to claim 4, wherein
the forming the sacrifice layer comprises: forming a sacrifice material layer covering the first electrode, wherein the sacrifice material layer is a strippable layer; forming a first photoresist layer on the sacrifice material layer; and performing a photolithography process on the sacrifice material layer by using the first mask and the first photoresist layer to form the sacrifice layer; and
a material of the first photoresist layer comprises a first photoresist, the pixel definition layer is formed by a photolithographic process using a second photoresist and the first mask, and photosensitivity of the first photoresist is opposite to that of the second photoresist.

8. The manufacturing method of the light emitting substrate according to claim 6, wherein
the first photoresist is negative photoresist and the second photoresist is positive photoresist; or, the first photoresist is positive photoresist and the second photoresist is negative photoresist.

9. The manufacturing method of the light emitting substrate according to claim 1, wherein the auxiliary electrode is formed before forming the first electrode, the auxiliary electrode is on a side, close to the partition portion of the pixel definition layer, of the first electrode.

10. The manufacturing method of the light emitting substrate according to claim 9, wherein
the forming the auxiliary electrode includes: forming a conductive material layer covering the pixel definition layer; and performing a photolithography process on the conductive material layer using the first mask and a first photoresist to form the auxiliary electrode; and
the pixel definition layer is formed by a photolithography process using the first mask and a second photoresist, and photosensitivity of the first photoresist is same as that of the second photoresist.

11. The manufacturing method of the light emitting substrate according to claim 5, wherein
the conductive material layer is formed by an evaporation method.

12. The manufacturing method of the light emitting substrate according to claim 1, wherein
a material of the first electrode is a metal material; and
a thickness of the first electrode is not more than 20 nm in a direction from a surface, away from the pixel definition layer, of the first electrode to a surface, close to the pixel definition layer, of the first electrode.

13. The manufacturing method of the light emitting substrate according to claim 1, further comprising:
forming a second electrode and a light emitting layer in the opening of the pixel definition layer, wherein
the second electrode is opposite to the first electrode, and the light emitting layer is between the first electrode and the second electrode; and
light emitted by the light emitting layer exits through the first electrode.

14. A light emitting substrate, comprising:
a pixel definition layer comprising an opening and a partition portion;
a first electrode comprising a first portion and a second portion, wherein the first portion is on the partition portion and covers at least a part of the partition portion, and the second portion is in the opening; and
an auxiliary electrode which is in contact with the first electrode in a surface-to-surface manner to be electrically connected with the first electrode, and is on the partition portion, wherein
the auxiliary electrode and the pixel definition layer have a substantially same pattern.

15. The light emitting substrate according to claim 14, wherein
the auxiliary electrode is on a side, away from the partition portion of the pixel definition layer, of the first electrode.

16. The light emitting substrate according to claim 14, wherein
the auxiliary electrode is on a side, close to the partition portion of the pixel definition layer, of the first electrode.

17. The light emitting substrate according to claim 14, wherein
a material of the first electrode is a metal material; and
a thickness of the first electrode is not more than 20 nm in a direction from a surface, away from the pixel definition layer, of the first electrode to a surface, close to the pixel definition layer, of the first electrode.

18. The light emitting substrate according to claim 14, further comprising:
a second electrode and a light emitting layer which are in the opening of the pixel definition layer, wherein
the second electrode is opposite to the first electrode, and the light emitting layer is between the first electrode and the second electrode; and
light emitted by the light emitting layer exits through the first electrode.

19. An electronic device, comprising the light emitting substrate according to claim 14.

20. The manufacturing method of the light emitting substrate according to claim 7, wherein
the first photoresist is negative photoresist and the second photoresist is positive photoresist; or, the first photoresist is positive photoresist and the second photoresist is negative photoresist.
